(19) United States
(12) Patent Application Publication
(10) Pub. No.: US 2026/0268952 A1
(43) Pub. Date: Sep. 10, 2026

(54) MEMORY ARRAY COLUMN ACCESS

(71) Applicant: Micron Technology, Inc., Boise, ID (US)

(72) Inventors: Xinyu Wu, Boise, ID (US); Yuan He, Boise, ID (US); Troy A. Manning, Boise, ID (US)

(21) Appl. No.: 19/554,089

(22) Filed: Mar. 2, 2026

Related U.S. Application Data
(60) Provisional application No. 63/766,770, filed on Mar. 4, 2025.

(51) Int. Cl. G11C 8/10; G11C 7/06; G11C 7/22

(52) U.S. Cl. CPC G11C 8/10; G11C 7/06; G11C 7/22

(57) ABSTRACT

Phase shift circuitry is described herein. Phase shift circuitry can receive a column select signal from the processing unit (PU). The phase shift circuitry can phase shift the column select signal to generate additional column select signals. The phase shift circuitry can provide the column select signal and the additional column select signals to the array of memory cells to access a plurality of lookup tables representing activation functions used to implement a machine learning model.

### PRIORITY INFORMATION

This application claims the benefit of U.S. Provisional Application Number 63/766,770, filed on Mar. 4, 2025, the contents of which are incorporated herein by reference.

### TECHNICAL FIELD

The present disclosure relates generally to memory, and more particularly to accessing columns of a memory array.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram of an array of memory cells in accordance with a number of embodiments of the present disclosure.

FIG. 3 is a block diagram of a half bank in accordance with a number of embodiments of the present disclosure.

FIG. 4A is a block diagram of drivers in accordance with a number of embodiments of the present disclosure.

FIG. 4B is a timing diagram for quad-phase staggering data in accordance with a number of embodiments of the present disclosure.

FIG. 5A is a block diagram of drivers in accordance with a number of embodiments of the present disclosure.

FIG. 5B is a timing diagram for dual-phase staggering data in accordance with a number of embodiments of the present disclosure.

FIG. 6 illustrates an example flow diagram of a method for accessing columns of a memory array in accordance with a number of embodiments of the present disclosure.

FIG. 7 illustrates an example machine of a computer system within which a set of instructions, for causing the machine to perform any one or more of the methodologies discussed herein, can be executed.

### DETAILED DESCRIPTION

The present disclosure relates to accessing columns of a memory array. A memory device can include an array of memory cells, sensing circuitry coupled to the array of memory cell, a processing unit (PU) coupled to the sensing circuitry, and phase shift circuitry coupled to the sensing circuitry and the PU. The phase shift circuitry can receive a column select signal from the PU and generate additional column select signals using the column select signal and a phase shifted clock signal. The phase shift circuitry can provide the column select signal and the additional column select signals to the array of memory cells to access a plurality of lookup tables representing activation functions used to implement an artificial neural network.

In previous approaches, a single column address can be used to access a single column of a memory array. Accessing a single column of a memory array limits how data is accessed. For example, a first column of each of a plurality of sub-arrays can be accessed using a single column address. However, in previous approaches multiple columns of a sub-array may not be accessed concurrently. Previous approaches can access multiple columns sequentially such that data is provided from the array of memory cells sequentially and the data is received sequentially by a device receiving the data.

In order to address these and other deficiencies of previous approaches, embodiments of the present disclosure implement phase shift circuitry to create multiple column select signals and implement an array of memory cells and sensing circuitry that utilize the multiple column select signals to access multiple columns of the array concurrently. In various examples, multiple columns of an array can be accessed concurrently to access multiple activation functions stored in the array of memory cells as lookup tables. The activation functions can be utilized by a PU coupled to the array of memory cells. The PU can initiate the access of the lookup tables utilizing a column select signal which can be used to generate multiple column select signals using a phase shifted clock signal. The multiple column select signals can be utilized to access the multiple rows of the array of memory cells. As used herein, the column select signals can also be referred to as column addresses.

As used herein, a PU can include hardware and/or firmware to perform a plurality of operations. The PU can include MAC units which include hardware and/or firmware for performing a plurality of multiplication operations and a plurality of accumulation operations referred to as MAC operations.

The PU can be used to implement a machine learning model. As used herein a machine learning model can provide learning by recognizing patterns and making predictions based on new data. A machine learning model can be an artificial neural network (ANN), for example. An ANN can be implemented using the MAC units. As used herein, ANNs can provide learning by forming probability weight associations between an input and an output. The probability weight associations can be provided by a plurality of nodes that comprise the ANN. The nodes together with weights, biases, and activation functions can be used to generate an output of the ANN based on the input to the ANN. A plurality of nodes of the ANN can be grouped to form layers of the ANN.

As used herein, artificial intelligence (AI) refers to the ability to improve an apparatus through “learning” such as by storing patterns and/or examples which can be utilized to take actions at a later time. Machine learning refers to a device’s ability to learn from data provided as examples. Machine learning can be a subset of AI. Neural networks, among other types of networks, can be classified as machine learning.

As used herein, “a number of” something refers to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

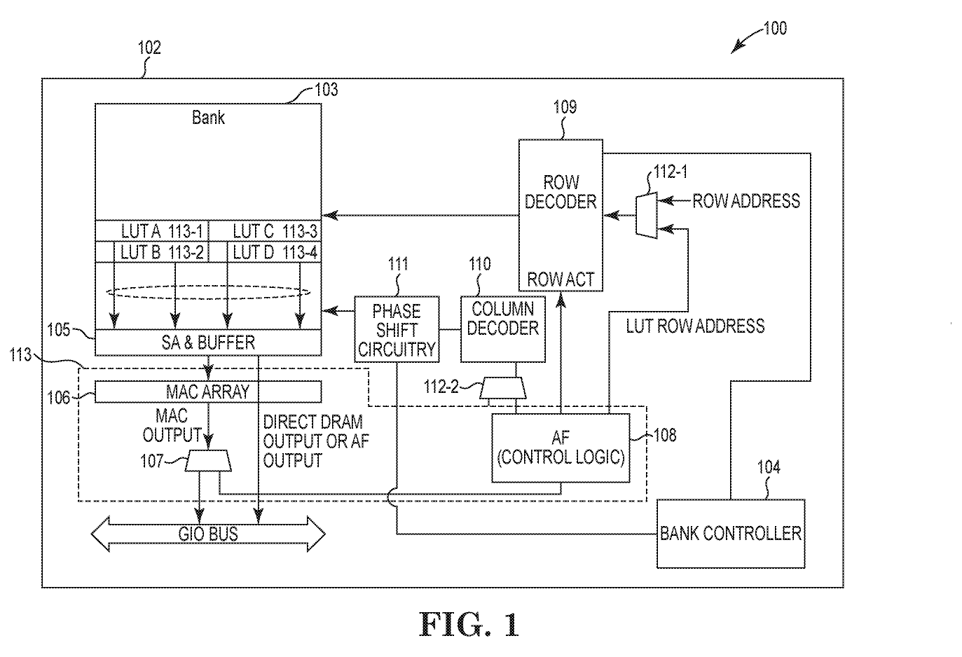

FIG. 1 is a block diagram of an apparatus in the form of a computing system 100 including a memory device 102 in accordance with a number of embodiments of the present disclosure. As used herein, a memory device 102, a bank 103 of memory cells, also referred to as a memory array 103 of memory cells, a host, a PU 113, and/or the bank controller 104 (e.g., the controller 104) might also be separately considered an “apparatus.”

In this example, system 100 includes a host (not shown) coupled to memory device 102 via an interface. The computing system 100 can be a personal laptop computer, a desktop computer, a digital camera, a mobile telephone, a memory card reader, or an Internet-of-Things (IoT) enabled device, among various other types of systems. Host can include a number of processing resources (e.g., one or more processors, microprocessors, or some other type of controlling circuitry) capable of accessing memory 102. The system 100 can include separate integrated circuits, or both the host and the memory device 102 can be on the same integrated circuit. For example, the host may be a system controller of a memory system comprising multiple memory devices 102, with the system controller providing access to the respective memory devices 102 by another processing resource such as a central processing unit (CPU).

The host is responsible for executing an operating system (OS) and/or various applications that can be loaded thereto (e.g., from memory device 102). The host can provide access commands to a memory device 102 via the interface.

For clarity, the system 100 has been simplified to focus on features with particular relevance to the present disclosure. The memory array 103 can be a DRAM array, SRAM array, STT RAM array, PCRAM array, TRAM array, RRAM array, NAND flash array, and/or NOR flash array, for instance. The array 103 can comprise memory cells arranged in rows coupled by access lines (which may be referred to herein as word lines or select lines) and columns coupled by sense lines (which may be referred to herein as digit lines or data lines). Although a single array 103 is shown in FIG. 1, embodiments are not so limited. For instance, memory device 102 may include a number of arrays 103 (e.g., a number of banks 103).

The memory device 102 includes address circuitry to latch address signals provided over the interface. The interface can include, for example, a physical interface employing a suitable protocol (e.g., a data bus, an address bus, and a command bus, or a combined data/address/command bus). Such protocol may be custom or proprietary, or the interface may employ a standardized protocol, such as Peripheral Component Interconnect Express (PCIe), Gen-Z, CCIX, or the like. Address signals are received and decoded by a row decoder 109 and a column decoder 110 to access the memory array 103. Data can be read from memory array 103 by sensing voltage and/or current changes on the sense lines using sensing circuitry 105. The sensing circuitry 105 can comprise, for example, sense amplifiers that can read and latch a page (e.g., row) of data from the memory array 103. I/O circuitry can be used for bi-directional data communication with host over the interface. Read/write circuitry is used to write data to the memory array 103 or read data from the memory array 103.

The memory device 102 decodes signals provided by the host. These signals can include chip enable signals, write enable signals, and address latch signals that are used to control operations performed on the memory array 103, including data read, data write, and data erase operations. In various embodiments, a controller of the memory device 102 is responsible for executing instructions received from the host. The controller can comprise a state machine, a sequencer, and/or some other type of control circuitry, which may be implemented in the form of hardware, firmware, or software, or any combination of the three.

In various instances, the memory device 102 can receive signals provided by the host including signals requesting operations to be performed by the PU 113. As used herein, the PU 113 can include hardware and/or firmware for performing operations, such as, for example, multiplication operations, using data provided by the memory array 103.

The memory device 102 also includes the bank controller 104, and the multiplexors (MUXs) 112-1, and 112-2. The memory device 102 also includes phase shift circuitry 111. The PU 113 includes a plurality of MAC units 106 (e.g., MAC array), a demultiplexor (DEMUX) 107. The PU 113 also includes input registers and accumulation registers, not shown.

The PU 113 further includes activation function circuitry 108 (alternatively referred to as “control logic”). The activation function circuitry 108 can control access to a plurality of activation functions stored in the memory array 103 as lookup tables. For example, the memory array 103 stores lookup tables 113-1 (“LUT A” shown in FIG. 1), 113-2 (“LUT b” shown in FIG. 1), 113-3 (“LUT C” shown in FIG. 1), 113-4 (“LUT D” shown in FIG. 1), referred to as lookup tables 113, corresponding to a plurality of activation functions. The lookup tables 113 can be stored in different portions of the memory array 103.

In various examples, the accumulated results of the MAC units 106 can be used to access a plurality of activation functions. For example, the activation functions can be stored in the memory array 103 as lookup tables 113. The accumulated results can be used as an index to the lookup tables 113 that represent activation functions. It may be computationally expensive to implement activation functions as formulas in the PU 113. The activation functions can be implemented in the memory device 103 as lookup tables 113.

The accumulated results can be provided to the activation function circuitry 108. The activation function circuitry 108 can generate a column select signal, a row address, and a row activation signal based on the accumulated results.

As shown in FIG. 1, the activation function circuitry 108 (e.g., AF) can be implemented in the PU 113 or can be implemented external to the PU 113. The activation function circuitry 108 can provide the column select signal to the column decoder 110. The activation function circuitry 108 can provide the row address and/or the row activation signal to the row decoder 109.

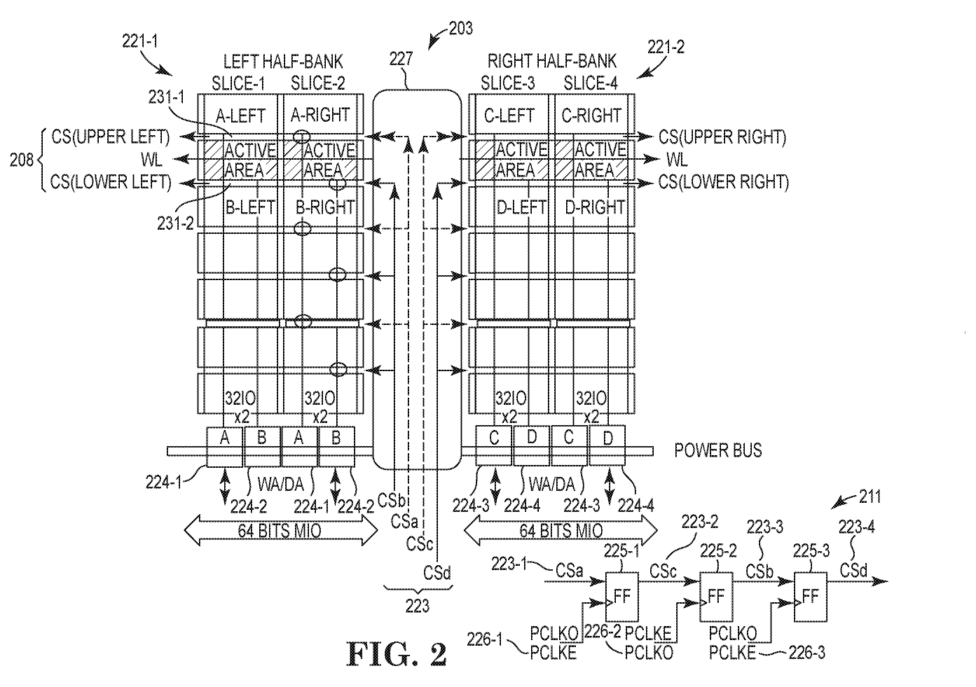

For example, the activation function circuitry 108 can provide the column select signal to a MUX 112-2. As used herein the column select signal can represent a column address used to select columns of the array of memory cells 103 to provide data from columns of the array to drivers (e.g., drivers 224 shown in FIG. 2) of the memory device. The MUX 112-2 can receive a column select signal from the activation function circuitry 108 and a different column select signal from the bank logic (not shown) of the memory device 102. The MUX 112-2 can utilize the column select signal or the different column select signal to move data from the sensing circuitry to drivers of the memory device 102. The bank logic can provide a control signal to the MUX 112-2 to cause the MUX 112-2 to select one of the column select signal or the different column select signal. As used herein, the drivers include hardware configured to drive a signal across one or more lines.

Responsive to selecting the column select signal, the MUX 112-2 can provide the column select signal to the phase shift circuitry 111. The phase shift circuitry 111 can generate additional column select signals from the column select signal utilizing a phase shifted clock signal, a plurality of flip-flops, and the column select signal. The column select signal and the additional column select signals can be referred to as a plurality of column select signals. The phase shift circuitry 111 can provide the plurality of column select signals to the sensing circuitry 105 of the memory array 103.

The activation function circuitry 108 can provide the row activation signals directly to the row decoder 109. The activation function circuitry 108 can also provide the row address to the activation function circuitry 108 via the MUX 112-1.

The MUX 112-1 can receive the row address from the activation function circuitry 108 and a different row address from the bank logic. The MUX 112-1 can select one of the row address and the different row address based on a control signal provided by the bank logic.

Responsive to receipt of a particular control signal, the MUX 112-1 can select the row address and can provide the row address to the row decoder 109. The row decoder 109 can activate a row of the memory array 103 based on receipt of the row address. The row address can be used to identify the row to activate.

Responsive to the activation of the row, the memory array 103 can provide data stored in memory cells coupled to the activation line to the sensing circuitry 105. The sensing circuitry 105 can utilize the column select signal provided by the phase shift circuitry 111 to transfer a subset of the data from the sensing circuitry 105 to drivers of the memory device 102. The subset of the data provided by the sensing circuitry 105 can be shifted in time using a phase shifted clock signal such that the subset of the data is provided sequentially in portions corresponding to different lookup tables. The receivers/drivers can receive the data received sequentially and can recombine the data. The data is recombined to allow the drivers to provide the data concurrently. As used herein, phase shifting describes the act of delaying a plurality of signals based on a phase shifted clock signal.

The drivers can provide the data concurrently to the PU 113. The PU can utilize the values of the lookup tables corresponding to the activation functions to access values of the activation function and utilize the values to perform additional multiplication operations. The PU 113 can utilize the outputs of the activation functions to determine whether to forward propagate signals received by a node of the ANN. The output of the PU 113 generated using the values of the lookup tables can be received by the DEMUX 107. The DEMUX 107 can output the results of the MAC units 106 to a global input/output (GIO) bus.

In various examples, the memory device 102 can be in a first mode or a second mode based on a mode register. The first mode can be used to output data out of the PU 113 to the GIO bus in a traditional manner. The second mode can be used to output data out of the PU 113 to the activation function circuitry 108 in examples where the activation function circuitry 108 is implemented externally to the PU 113. Providing modes for the memory device 102 allows the memory device 102 to be used in a traditional manner when in a first mode or allows the memory device 102 to be used to store and provide lookup tables corresponding to activation functions for use by the PU 113 to perform a plurality of operations when in a second mode. The PU 113 can provide accumulated results to the column decoder 110 as the column select signal to cause the column decoder 110 to provide the column select signal to the phase shift circuitry 111.

FIG. 2 is a block diagram of an array of memory cells 203 in accordance with a number of embodiments of the present disclosure. The array of memory cells 203 includes two half arrays 221-1, 221-2, referred to as half arrays 221. The array of memory cells 203 also includes a plurality of sense amplifier strips 231-1, 231-2 that combined constitute sensing circuitry. The sense amplifier strips 231-1, 231-2 can be referred to as sense amplifier strips 231.

The array of memory cells 203 can provide data to the drivers 224-1, 224-2, 224-3, 224-4, referred to as drivers 224. As used herein, the drivers 224 include hardware to amplify signals received from the sense amplifier strips 231 and drive the signals across the GIO bus.

FIG. 2 also shows the phase shift circuitry 211. The phase shift circuitry 211 can include a plurality of flip-flops 225-1, 225-2, 225-3, referred to as flip-flops 225. The flip-flops can be used to generate the column select signals 223-2 (“CSC” shown in FIG. 2), 223-3 (“CSb” shown in FIG. 2), 223-4 (“CSd” shown in FIG. 2) from the column select signal 223-1. The column select signals 223-1, 223-2, 223-2, 223-4 can be referred to as column select signals 223.

The phase shift circuitry 211 can provide the column select signals 223 to the array of memory cells 203. For example, the sense amplifier strips 231 can receive the column select signals 223 provided by the phase shift circuitry 211. The array of memory cells 203 can be divided into two portions by a column 227. Dividing the column 227 can include dividing a sub-array (e.g., active area) and dividing the sensing circuitry. For example, the array area of the sub-arrays can be divided such that there is no conductance between shared word lines of the different half banks 221.

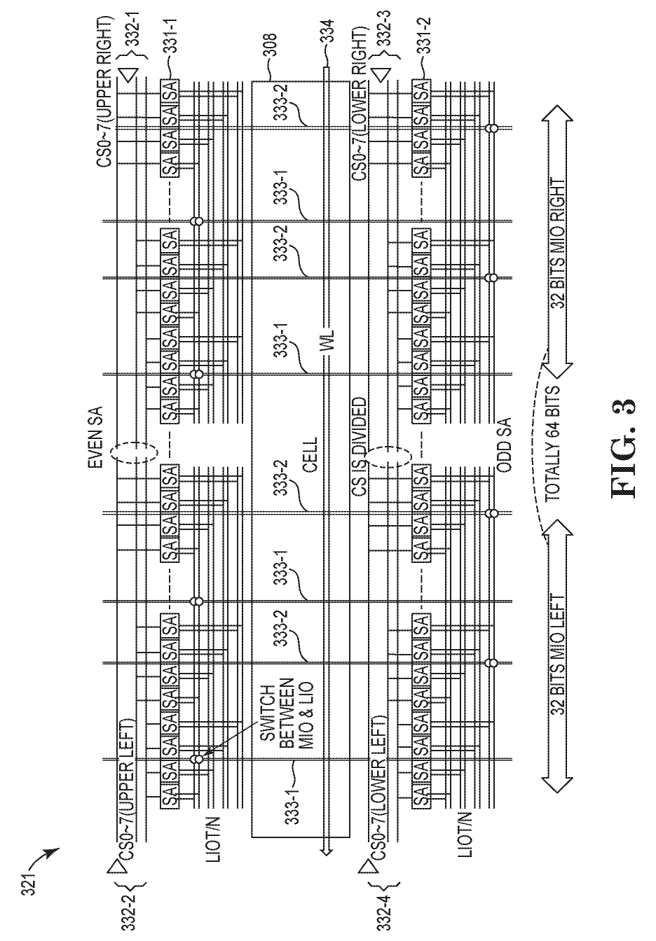

The column 227 can provide a space for the column selects signals 223 to be provided to the sub-arrays 208. As used herein, a sub-array can include complimentary sense amplifier strips and an array area. The column select signals 223 can be provided via a plurality of lines that provide the column select signals 223 to column select lines of the sensing circuitry. The lines that carry the column select signals 223 can be implemented in the column 227 that divides the array of memory cells 203 into the half arrays 221. FIG. 3 further describes a half array. In a plurality of examples, the column 227 can be comprised of insulative components that can separate the sub-portions between the half arrays 221.

The phase shift circuitry 211 includes the flip-flop 225-1. The column select signal 223-1 can be provided to the array of memory cells 203 without experiencing a delay and can be provided to the phase shift circuitry 211. The flip-flop 225-1 can receive the column select signal 223-1 (CSa) and a phase shifted clock signal 226-1 (PCLKO/PCLKE). Upon receipt of the phase shifted clock signal 226-1, the flip-flop 225-1 can generate and provide a column select signals 223-2 (CSc) to the flip-flop 225-2. The column select signal 223-2 can be generated after a delay from receipt of the column select signal 223-1. The delay can correspond to the phase shifting of a clock signal 226-1 (e.g., the phase shifted clock signal 226-1) that generates the phase shifted clock signal 226-2.

Responsive to generating the column select signal 223-2 (CSc), the column select signal 223-2 can be provided via a plurality of lines to the array of memory cells 203. The column 227 can receive the column select signal 223-2 can provide the column select signal 223-2 to one of the half banks 221. In the example of FIG. 2, the column select signal 223-2 is provided to the half bank 221-2.

The flip-flop 225-2 can receive the column select signal 223-2 and a phase shifted clock signal 226-2 (PCLKE/PCLKO). The phase shifted clock signal 226-2 is phase shifted relative to the phase shifted clock signal 226-1. The flip-flop 225-2 can generate and provide the column select signal 223-3 (CSb) to the flip flop 225-3 and to a half bank 221 of the array of memory cells 203.

Responsive to generating the column select signal 223-3 (CSb), the column select signal 223-3 can be provided to the array of memory cells 203. The column 227 can receive the column select signal 223-3 via a plurality of lines and can provide the column select signal 223-3 to one of the half banks 221. In the example of FIG. 2, the column select signal 223-3 is provided to the half bank 221-1.

The flip-flop 225-3 can receive the column select signal 223-3 and the phase shifted clock signal 226-3 (PCLKO/PCLKE). The phase shifted clock signal 226-3 is phase shifted relative to the phase shifted clock signal 226-2 and is on a same phase as the phase shifted clock signal 226-1. The flip-flop 225-3 can generate the column select signal 223-4 (CSd) using the phase shifted clock signal 226-3 and the column select signal 223-3. The flip-flop 225-4 can generate and provide the column select signal 223-4 (CSd).

Responsive to generating the column select signal 223-4 (CSd), the column select signal 223-4 can be provided to the array of memory cells 203. The column 227 can receive the column select signal 223-4 via a plurality of lines and can provide the column select signal 223-4 to one of the half banks 221. In the example of FIG. 2, the column select signal 223-4 is provided to the half bank 221-2.

The column select signals 223 can be provided to each of the sense amplifier strips 231 of the array of memory cells 203. For example, the column select signal 223-1 can be provided to the even sense amplifiers of the half bank 221-1. The column select signal 223-3 can be provided to the odd sense amplifiers of the half bank 221-1. The column select signals 223-2 can be provided to the even sense amplifiers of the half bank 221-2. The column select signals 223-4 can be provided to the odd sense amplifiers of the half bank 221-2.

FIG. 3 is a block diagram of half bank 321 in accordance with a number of embodiments of the present disclosure. The half bank 321 includes a half sub-array 308 of the memory array. The half bank 321 also includes sense amplifiers 331-1, 331-2, referred to as sense amplifiers 331. The sense amplifiers 331 shown comprise half of a sense amplifier strip that extends to the corresponding other half bank (not shown). The sense amplifiers 331-1 can be even sense amplifiers of the sense amplifier strip and the sense amplifiers 331-2 can be odd sense amplifiers of the sense amplifier strip. The half bank 321 also includes GIO lines 333-1, 333-2, referred to as GIO lines 333.

The half bank 321 further includes column select lines 332-1,332-2, 332-3, 332-4, referred to as column select lines 332. The column select lines 332-1, 332-2 can comprise a single column select line that is divided. The column select line 332-1 and the column select line 332-2 can be insulated from each other. The column select line 332-3 and the column select line 332-4 can also comprise a single column select line that is divided and can be insulated from each other. The column select lines 332 can be divided to accommodate independent access to the columns as respective LUTs on the same row of a bank, such that one or multiple LUTs can be fitted into a row to achieve fair utilization of memory bits and looking up the values based on column select without disturbing other portions of the memory row.

The column select lines 332 can provide the column select signals to the sense amplifiers 331. For example, the column select lines 332-1, 332-2 can provide a first column select signal (e.g., column select signal 223-1 of FIG. 2) to the sense amplifiers 331-1. The column select lines 332-3,332-4 can provide a second column select signal (e.g., column select signal 223-3 of FIG. 2) to the sense amplifiers 331-2.

In the example of FIG. 3, the sense amplifiers 331 can receive data stored in the memory cells of the memory array 203 coupled to a word line 334. The word line 334 can be activated by the row decoder 109 of FIG. 1. The sense amplifiers 331 can select a portion of the data based on the column select signals received by the sense amplifiers 331. For example, if the column select signal corresponds to a column address of a first column, then every first sense amplifier of the sense amplifiers 331-1 can provide a portion of the data received by the sense amplifiers 331-1 to the drivers.

The other half bank of the sub-array can receive a different column address corresponding to, for example, a second column such that every sense amplifier of the even sense amplifiers of the other half bank provide a different portion of the data received by the even sense amplifiers of the other half bank to the drivers. The portion can correspond a lookup table corresponding to a first activation function while the different potion can correspond to a different lookup table corresponding to a second activation function. The sense amplifiers can provide the portions of the data to the drivers utilizing the IO data lines which are multiplexed between MIO (Main IO) and LIO (Local IO) lines 333.

The sense amplifiers 331-2 can provide different lookup table values corresponding to different activation function. The sense amplifiers 331-2 can receive, for example, a third column select signal (e.g., CSb) used to access values of a lookup table corresponding to another activation function.

FIG. 3 shows the column select lines 332-1, 332-2 coupled to the sense amplifiers 331-1 as being composed of eight lines and the column select lines 332-3, 332-4 coupled to the sense amplifiers 331-2 as also being composed of eight lines. Each of the eight column select lines coupled to the sense amplifiers 331-1 can be divided. Each of the eight column select lines coupled to the sense amplifiers 331-2 can also be divided.

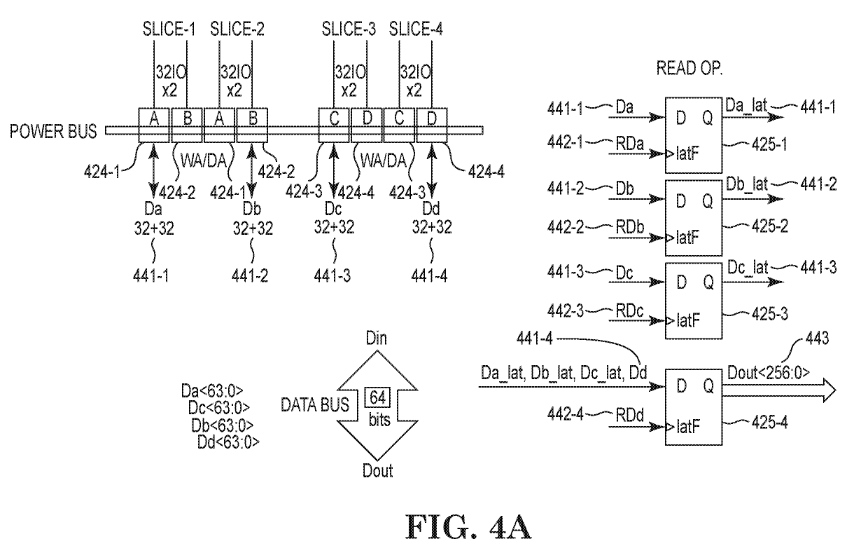

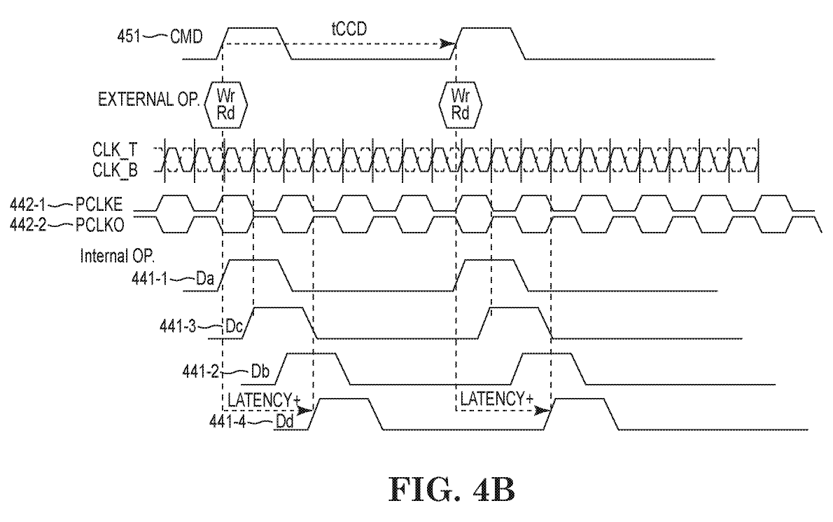

FIG. 4A is a block diagram of drivers 424-1, 424-2, 424-3, 424-4 in accordance with a number of embodiments of the present disclosure. The drivers 424-1, 424-2, 424-3, 424-4 can be referred to as drivers 424.

The drivers 424-1 can receive data from even sense amplifiers of a first half bank. The drivers 424-2 can receive data from odd sense amplifiers of the first half bank. The drivers 424-3 can receive data from even sense amplifiers of a second half bank. The drivers 424-4 can receive data from odd sense amplifiers of the second half bank.

The data received by the drivers 424-1 can correspond to a first lookup table corresponding to a first activation function. The data received by the drivers 424-2 can correspond to a second lookup table corresponding to a second activation function. The data received by the drivers 424-3 can correspond to a third lookup table corresponding to a third activation function. The data received by the drivers 424-4 can correspond to a fourth lookup table corresponding to a fourth activation function.

The drivers 424 can receive the data sequentially. For example, the drivers 424-1 can receive first data (Da) prior to receipt of second data by the drivers 424-2. The drivers 424-2 can receive second data (Db) prior to receipt of the third data by the drivers 424-3. The drivers 424-3 can receive third data (Dc) prior to receipt of fourth data (Dd) by the drivers 424-4.

The driver 424 can combine the data received sequentially to provide the first data, the second data, the third data, and the fourth data concurrently to the PU (e.g., the PU 113 shown in FIG. 1). The drivers can recombine the first data, the second data, the third data, and the fourth data utilizing the flip-flops 425-1, 425-2, 425-3, 425-4, referred to as flip-flops 425.

For example, the flip-flop 425-1 can receive the data 441-1 and a clock signal 442-1. Utilizing the clock signal 442-1, the flip-flop 425-1 can provide the data 441-1 to the flip-flop 425-4. The flip-flop 425-4 can receive the data 441-1 concurrently with the data 441-2, 441-3, 441-4. The flip-flop 425-2 can receive the data 441-2 and a clock signal 442-2. Utilizing the clock signal 442-2, the flip-flop 425-2 can provide the data 441-2 to the flip-flop 425-4 concurrently with the data 441-1, 441-3, 441-4.

The flip-flop 425-3 can receive the data 441-3 and a clock signal 442-3. Utilizing the clock signal 442-3, the flip-flop 425-3 can provide the data 441-3 to the flip-flop 425-4 concurrently with the data 441-1, 441-2, 441-4. The flip-flop 425-4 can receive the data 441-4 and a clock signal 442-4. Utilizing the clock signal 442-4, the flip-flop 425-4 can provide the data 441-1, 441-2, 441-3, 441-4 to the PU. In various examples, the flip-flops 425 can be incorporated in the drivers 424. The flip-flops 425 can also be implemented externally to the drivers 424.

The data 441 can be combined using quad-phase staggering by combining four groups of data into a single data that can be provided to the PU concurrently. Each of the data 441-1, 441-2, 441-3, 441-4 can comprise 64 bits such that the combined data 443 comprises 256 bits of data. Combining the data 441-1, 441-2, 441-3, 441-4 can include combining respective values of different lookup tables or different lookup tables into a data 443. Providing the data 443 to the PU includes providing the values of the different lookup tables to the PU to allow the PU to implement multiple activation functions concurrently.

The process used to output the values of the lookup tables stored in the memory array can also be used to write the values of the lookup tables to the memory array. For example, the receivers 424 may be used to provide input data representing values of lookup tables to the array of memory cells.

FIG. 4B is a timing diagram for quad-phase staggering data in accordance with a number of embodiments of the present disclosure. The data 441-1, 441-2, 441-3, 441-4 can be referred to as data 441. FIG. 4 also shows phase shifted clock signals 442-1, 442-2, also referred to as phase shifted clock signals 442.

The phase shifted clock signals 442 can be phase shifted relative to each other. For example, the phase shifted clock signal 442-1 can be phase shifted to generate the phase shifted clock signals 442-2. The phase shifted clock signal 442-1 can be high when the phase shifted clock signal 442-2 is low. The phase shifted clock signal 442-2 can be high when the phase shifted clock signal 442-1 is low.

The phase shifting of the clock signals 442 can allow for the transfer of data from the sense amplifiers (e.g., the sense amplifiers 331-1 and 331-2 shown in FIG. 3) to the drivers (e.g., the drivers 424-1, …, 424-4 shown in FIG. 4A) in a staggered manner. For example, in a quad-phase the data 441 can be provided from the sense amplifiers to the drivers using the phase shifted clock signals 442 such that a portion of the data 441 is provided each time one of the phase shifted clock signals 442 is high. For instance, the data 441-1 can be provided to the drivers when the phase shifted clock signal 442-1 is high and the phase shifted clock signal 442-2 is low; the data 441-3 can be provided to the drivers when the phase shifted clock signal 442-2 is high and the phase shifted clock signal 442-1 is low; the data 441-2 can be provided to the drivers when the phase shifted clock signal 442-1 is high and the phase shifted clock signal 442-2 is low; the data 441-4 can be provided to the drivers when the phase shifted clock signal 442-2 is high and the phase shifted clock signal 442-1 is low. More particularly, as illustrated in FIG. 4B, the provision of the data 441-1 is initiated on a rising edge of the phase shifted clock signal 442-1; the provision of the data 441-3 is subsequently initiated on a rising edge of the phase shifted clock signal 442-2; the provision of the data 441-2 is subsequently initiated on a subsequent rising edge of the phase shifted clock signal 442-1; and the provision of the data 441-4 is subsequently initiated on a subsequent rising edge of the phase shifted clock signal 442-2.

The data 441 can be provided to the drivers in a delayed sequential manner such that the drivers receive the data 441 within the column-to-column delay (tCCD) corresponding to a command 451 (e.g., a read command or a write command). For example, a read command may be provided to the memory device (e.g., external operation). Internally to the memory device, the data 441 can be sequentially transferred to the drivers based on the phase shifted clock signals 442 in a duration of time used to execute a read command due to the tCCD.

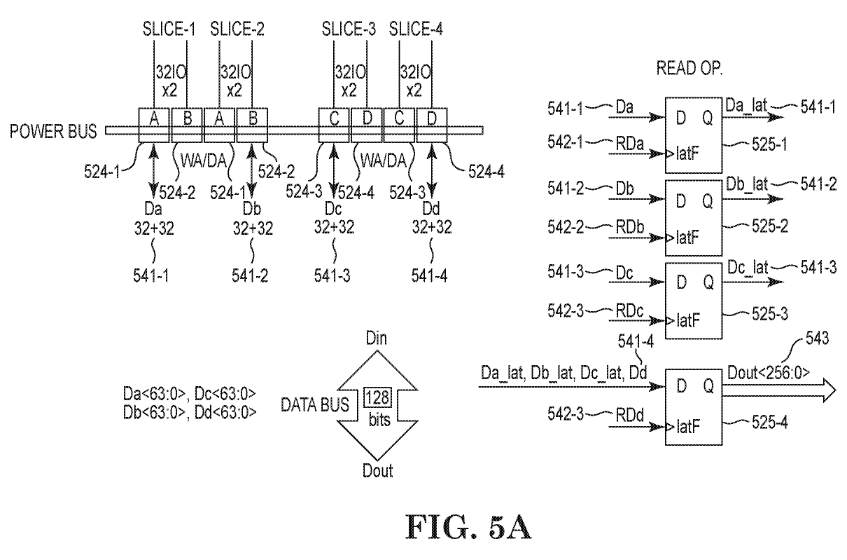

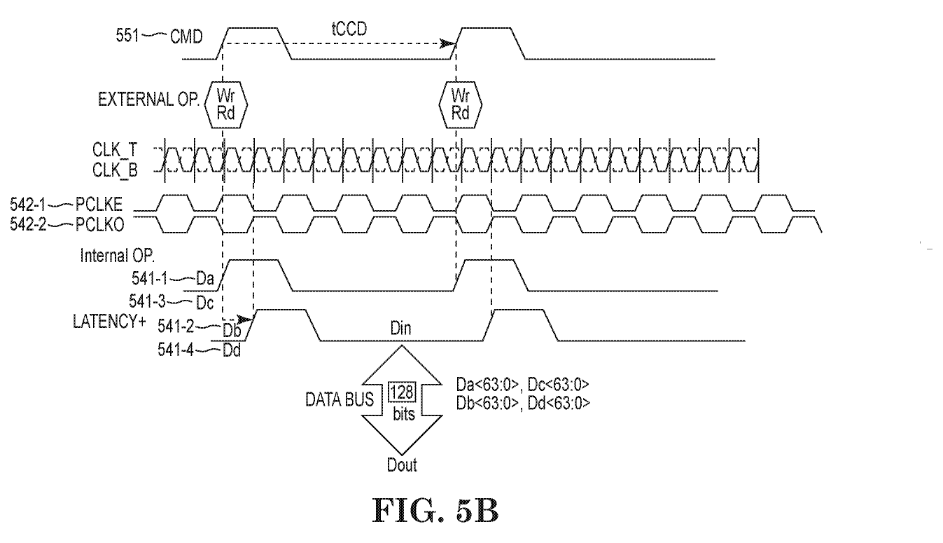

FIG. 5A is a block diagram of drivers 524-1, 524-2, 524-3, 524-4 in accordance with a number of embodiments of the present disclosure. The drivers 524-1, 524-2,524-3, 524-4 can be referred to as drivers 524.

The drivers 524-1 can receive data from even sense amplifiers of a first half bank. The drivers 524-2 can receive data from odd sense amplifiers of the first half bank. The drivers 524-3 can receive data from even sense amplifiers of a second half bank. The drivers 524-4 can receive data from odd sense amplifiers of the second half bank.

The data received by the drivers 524-1 can correspond to a first lookup table corresponding to a first activation function. The data received by the drivers 524-2 can correspond to a second lookup table corresponding to a second activation function. The data received by the drivers 524-3 can correspond to a third lookup table corresponding to a third activation function. The data received by the drivers 524-4 can correspond to a fourth lookup table corresponding to a fourth activation function.

The data received by the drivers 524 can be sequentially received using a dual-phase approach. For example, the drivers 524-1 can receive first data (Da) and third data (Dc) prior to receipt of second data (Db) and fourth data (Dd) by the drivers 524-2.

The driver can combine the data received sequentially to provide the first data, the second data, the third data, and the fourth data concurrently to the PU (e.g., the PU 113 shown in FIG. 1). The drivers can recombine the first data, the second data, the third data, and the fourth data utilizing the flip-flops 525-1, 525-2, 525-3, 525-4, referred to as flip-flops 525.

For example, the flip-flop 525-1 can receive the data 541-1 and a clock signal 542-1. Utilizing the clock signal 542-1, the flip-flop 525-1 can provide the data 541-1 to the flip-flop 525-4. The flip-flop 525-4 can concurrently receive the data 541-1 with the data 541-2, 541-3, 541-4. The flip-flop 525-2 can receive the data 541-2 and a clock signal 542-2. Utilizing the clock signal 542-2, the flip-flop 525-2 can provide the data 541-2 to the flip-flop 525-4 concurrently with the data 541-1, 541-3, 541-4.

The flip-flop 525-3 can receive the data 541-3 and a clock signal 542-3. Utilizing the clock signal 542-3, the flip-flop 525-3 can provide the data 541-3 to the flip-flop 525-4 concurrently with the data 541-1, 541-2, 541-4. The flip-flop 525-4 can receive the data 541-4 and a clock signal 542-4. Utilizing the clock signal 542-4, the flip-flop 525-4 can provide the data 541-1, 541-2, 541-3, 541-4 to the PU. In various examples, the flip-flops 525 can be incorporated in the drivers 524. The flip-flops 525 can also be implemented externally to the drivers 524.

The data 541 can be combined using dual-phase staggering by combining two groups of data into a single data that can be provided to the PU concurrently. The first group of data can include the data 541-1, 541-3 while the second group of data includes the data 541-2, 542-4.

Each of the data 541-1, 541-2, 541-3, 541-4 can comprise 64 bits such that the combined data 543 comprises 256 bits of data. Combining the data 541-1, 541-2, 541-3, 541-4 can include combining respective values of different lookup tables into a data 543. Providing the data 543 to the PU includes providing the values of the different lookup tables to the PU to allow the PU to implement multiple activation functions concurrently.

FIG. 5B is a timing diagram for dual-phase staggering data in accordance with a number of embodiments of the present disclosure. The data 541-1, 541-2, 541-3, 541-4 can be referred to as data 541. FIG. 5 also shows phase shifted clock signals 542-1, 542-2, also referred to as phase shifted clock signals 542 and a command 551.

The phase shifted clock signals 542 can be phase shifted relative to each other. For example, the phase shifted clock signal 542-1 can be phase shifted to generate the phase shifted clock signals 542-2. For example, the phase shifted clock signal 542-1 can be high when the phase shifted clock signals 542-2 is low, while the phase shifted clock signals 542-2 can be high when the phase shifted clock signal 542-1 is low.

The phase shifting of the clock signals 542 can allow for the transfer of data from the sense amplifiers (e.g., the sense amplifiers 331-1 and 331-2 shown in FIG. 3) to the drivers (e.g., the drivers 524-1, …, 524-4 shown in FIG. 5A) in a staggard manner consistent with the execution of the command 551 (e.g., read command). For example, in a dual-phase the data 541 can be provided from the sense amplifiers to the drivers using the phase shifted clock signals 542 such that a portion of the data 541 is provided each time one of the phase shifted clock signals 542 is high. For instance, the data 541-1, 541-3 can be provided to the drivers when the phase shifted clock signal 542-1 is high and the phase shifted clock signal 542-2 is low. The data 541-2, 541-4 can be provided to the drivers when the phase shifted clock signal 542-2 is high and the phase shifted clock signal 542-1 is low. More particularly, as illustrated in FIG. 5B, the provision of the data 541-1, 541-3 is initiated on a rising edge of the phase shifted clock signal 542-1, while the provision of the data 541-2, 541-4 is subsequently initiated on a rising edge of the phase shifted clock signal 542-2.

The data 541 can be provided to the drivers in a delayed sequential manner such that the drivers receive the data 541 within the column-to-column delay (tCCD) corresponding to a read command 551 or a write command. For example, a read command may be provided to the memory device (e.g., external operation). Internally to the memory device, the data 541 can be sequentially transferred to the drivers based on the phase shifted clock signals 542 in a duration of time used to execute a read command due to the tCCD.

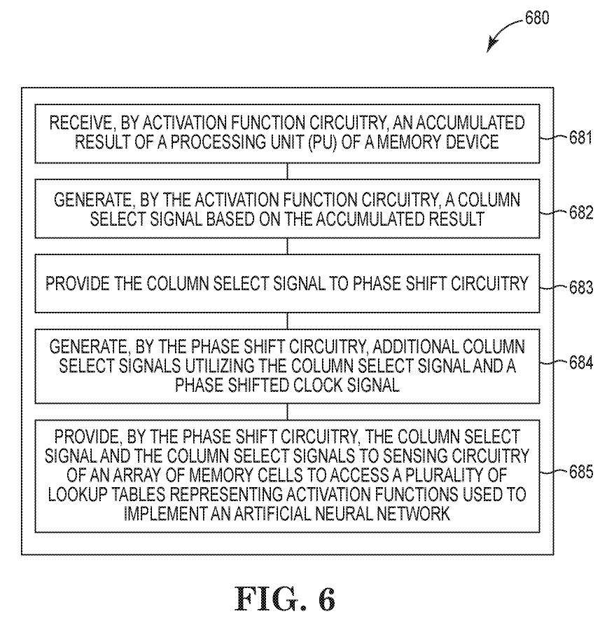

FIG. 6 illustrates an example flow diagram of a method 680 for accessing columns of a memory array in accordance with a number of embodiments of the present disclosure. The method can be executed by a memory device of a computing system. For example, the method can be executed by a PU, a phase shift circuitry, or an activation function circuitry of the memory device that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 680 is performed by the phase shift circuitry 111 of FIG. 1 and the activation function circuitry memory controller 108 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 681, the activation function circuitry 108 of FIG. 1 can receive an accumulated result from a PU 113 of a memory device 102 of FIG. 1. The PU can provide the accumulated results from accumulation registers to a DEMUX 107 of FIG. 1. For example, the accumulation registers can provide an accumulated result generated by the MAC units 106 of FIG. 1.

The DEMUX can, based on a control signal, provide the accumulated result too the activation function circuitry. In various examples, the bank logic, memory controller, and/or the activation function circuitry can provide the control signal to the DEMUX.

At 682, the activation function circuitry can generate a column select signal based on the accumulated result. For example, the activation function circuitry can great the accumulated results as the column select signal. The activation function circuitry can perform a plurality of operations using the accumulated result to generate the column select signal. Noting that the column select signal can be a column address, the activation function circuitry can process the accumulated result to generate the column select signal.

At 683, the activation function circuitry can provide the column select signal to phase shift circuitry 111 of FIG. 1. For example, the activation function circuitry can provide the column select signal to a column decoder. The column decoder can provide the column select signal to the phase shift circuitry.

At 684, the phase shift circuitry can generate additional column select signals utilizing the column select signal and a phase shifted clock signal. Phase shifting the column select signal describes the creation of multiple column select signals that are delayed one from another based on a phase shifted clock signal. For example, the phase shift circuitry can create additional column select signals from the column select signals using a plurality of flip-flops and a plurality of phase shifted clock signals.

Each of the plurality of column select signals can be provided to different portions of the sensing circuitry coupled to an array of memory cells in a time shifted manner. For example, a first column select signal can be provided to the sensing circuitry. A second column select signal can be provided after a predetermined amount of time has lapsed since the first column select signal was provided to the sensing circuitry. The delay between providing the first column select signal and the second column select signal can be dictated using a phase shifted clock signals. For instance, the first column select signal can be provided when a first phase shifted clock signal is high and the second phase shifted clock signal is low while the second column select signal is provided when a second phase shifted clock signal is high and the first phase shifted clock signal is low.

At 685, the phase shift circuitry can provide the column select signal and the additional column select signals to sensing circuitry of an array of memory cells to access a plurality of lookup tables representing activation functions used to implement an artificial neural network. The column select signals can be shifted in time relative to a phase shifted clock signal as described above. Each of the phase shifted column select signals can comprise a plurality of column select signals. For example, a first column select signal that represents a first column address can be provided to the sensing circuitry using a plurality of lines each carrying a bit of the first column address. For example, column address can be represented using eight bits each provided using a different line to the sensing circuitry.

The sensing circuitry can provide data corresponding to a plurality memory cells coupled to a plurality of sense lines (e.g., columns) having different addresses and corresponding to the column select signal and the additional column select signals. For example, each of the additional column select signals and the column select signal can provide a different column address to different portions of the sensing circuitry. The sensing circuitry can provide data provided via sense lines (e.g., columns) having said different column addresses to the PU.

The data from each of the plurality of columns of the memory array is provided from the sensing circuitry to a plurality of drivers sequentially. For example, second data provided using sense lines having a second column address can be shifted in time relative to first data provided sing sense lines having a first column address. The data may be provided to the drivers in a time shifter manner because it may not be possible to provide the data to the drivers concurrently due to the limitations of the hardware. For example, there may be more bits that comprise the data than there are GIO lines such that it is not possible to provide the bits using the GIO lines concurrently.

The drivers can receive the time shifted bits of the data and can recombine the time shifted data. The drivers can provide the recombined data concurrently to the PU.

In various examples, the data can comprise values of a plurality of lookup tables. The drivers can provide the plurality of lookup tables (e.g., values of a plurality of lookup tables) concurrently to the PU. The drivers can provide the values of the plurality of lookup tables concurrently utilizing a plurality of flip-flops and a clock signal. For example, the drivers can recombine the plurality of data values of the different lookup tables such that the drivers can provide the plurality of data values of the different lookup tables at a same time to the PU even though the drivers received the plurality of data values of the different lookup tables at different times utilizing the flip-flops. The clock signal used to recombine the plurality of values of the different lookup tables can be phase shifted to allow the data values to be provided to a last flipflop at the same time, where the last flip-flop provides the recombined values to the PU.

For example, a first portion of the data and a second portion of the data can be sequentially provided to a last flip-flop from the plurality of flip-flops. The first portion and the second portion of the data can be concurrently provided from the last flip-flop to the PU.

In various examples, an apparatus an apparatus can comprise an array of memory cells, sensing circuitry coupled to the array of memory cells, a PU coupled to the sensing circuitry, and phase shift circuitry coupled to the sensing circuitry and the PU. The phase shift circuitry can receive a column select signal from the PU. The phase shift circuitry can generate additional column select signals using the column select signal and a phase shifted clock signal. The phase shift circuitry can also provide the column select signal and the additional column select signals to the array of memory cells to access a plurality of lookup tables representing activation functions used to implement a machine learning model such as an artificial neural network.

The phase shift circuitry can receive the column select signal from the PU via a column decoder. The PU can provide the column select signal to a MUX, wherein the MUX provides the column select signal to the phase shift circuitry. The MUX can receive the column select signal from the PU and a different column select signal from bank logic. The MUX can provide one of the column select signal or the different column select signal to the column decoder based on a control signal received from a bank controller. A column decoder can provide the column select signal to the phase shift circuitry responsive to receipt of the column select signal from the MUX.

The PU can provide a row activation signal to a row decoder and a row address and to a MUX coupled to the row decoder. The MUX coupling the PU to the row decoder can receive the row address from the PU and a different row address from bank logic. The MUX can provide one of the row address or the different row address to the row decoder based on a control signal received from a bank controller. The row decoder can activate a row of the array of memory cells based on receipt of the row address and receipt of the activation signal.

The phase shift circuitry can generate the additional column select signals utilizing a plurality of flip-flops, the column select signal, and the phase shifted clock. Phase shifting a column select signal can include creating a new column select signal shifting the newly created column select signal in time relative to the original column select signal. Shifting a newly created column select signal can include providing the newly created column select signal after the original column selected signal is provided based on a phase shifted clock signal. An output of each of the plurality of flip-flops can be an additional column select signal from the additional column select signals and can be provided to a different flip-flop from the plurality of flip-flops. The output of each of the plurality of flip-flops can be provided as an input to a different flip-flop until the output of a next to last flip-flop is provided as an input to a last flip-flop from the plurality of flip-flops.

In various examples, an apparatus can include sensing circuitry of an array of memory cells, a PU coupled to the sensing circuitry, and phase shift circuitry coupled to the sensing circuitry and the PU. The phase shift circuitry can receive a column select signal from the processing unit. The phase shift circuitry can generate additional column select signals using the column select signal and a phase shifted clock signal. The phase shift circuitry can provide the column select signal and the additional column select signals to the array of memory cells to access a plurality of lookup tables representing activation functions used to implement an artificial neural network. For example, the column select signal and the additional column select signal can be provided to sensing circuitry of the array of memory cells.

The sensing circuitry can receive the column select signal and the additional column select signals via column select lines that are divided into a plurality of portions. The sensing circuitry can provide the column select signal and the additional column select signals to a plurality of sense amplifiers utilizing the column select lines to cause data to be provided to drivers sequentially. The plurality of sense amplifiers can receive each of the column select signal and the additional column select signals utilizing a different portion of the plurality of portions of the column select lines. For example, a first portion of the sense amplifiers can receive one of the column select signals or the additional column select signals via a first portion of the first column select line while a second portion of the sense amplifiers receive a different column select signal or the additional column select signal via a second portion of the first column select line. The sensing circuitry can provide the data sequentially to a plurality of drivers responsive to sequential receipt of the column select signal and the phase shifted additional column select signal.

The PU can, responsive to a bank of the memory device being in a first mode, provide accumulated values via a plurality of GIO lines. Responsive to the bank of the memory device being in a second mode, the PU can provide the accumulated values to a column decoder as the column select signal to cause the column decoder to provide column select signal to the phase shift circuitry.

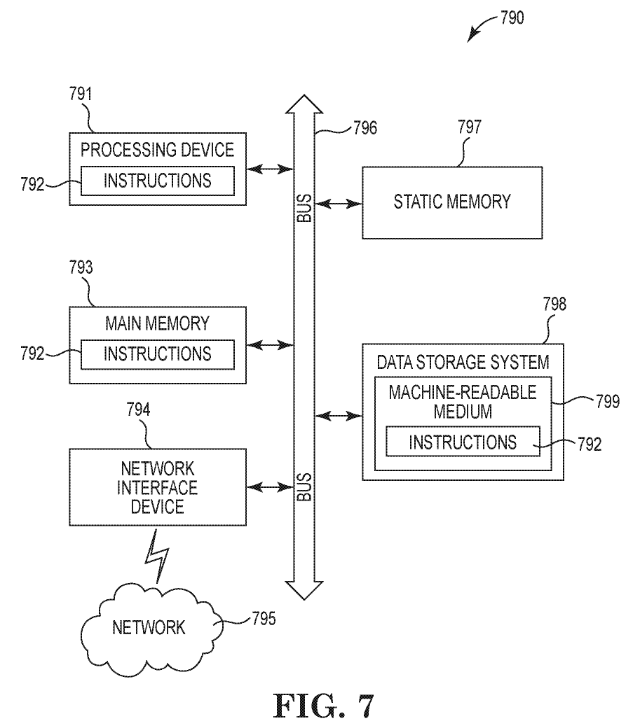

FIG. 7 illustrates an example machine of a computer system 790 within which a set of instructions, for causing the machine to perform any one or more of the methodologies discussed herein, can be executed. In some embodiments, the computer system 790 can correspond to a host system that includes, is coupled to, or utilizes a memory system (e.g., the memory device 120 of FIG. 1) or can be used to perform the operations of the PU controller (e.g., the PU controller 105 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 790 includes a processing device 791, a main memory 793 (e.g., read-only memory (ROM), flash memory, dynamic random access memory (DRAM) such as synchronous DRAM (SDRAM) or Rambus DRAM (RDRAM), etc.), a static memory 797 (e.g., flash memory, static random access memory (SRAM), etc.), and a data storage system 798, which communicate with each other via a bus 796.

Processing device 791 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 791 can also be one or more special-purpose processing devices such as an application specific integrated circuit (ASIC), a field programmable gate array (FPGA), a digital signal processor (DSP), network processor, or the like. The processing device 791 is configured to execute instructions 792 for performing the operations and steps discussed herein. The computer system 790 can further include a network interface device 797 to communicate over the network 795.

The data storage system 798 can include a machine-readable storage medium 799 (also known as a computer-readable medium) on which is stored one or more sets of instructions 792 or software embodying any one or more of the methodologies or functions described herein. The instructions 792 can also reside, completely or at least partially, within the main memory 793 and/or within the processing device 791 during execution thereof by the computer system 790, the main memory 793 and the processing device 791 also constituting machine-readable storage media.

In one embodiment, the instructions 792 include instructions to implement functionality corresponding to the PU controller 105 of FIG. 1. While the machine-readable storage medium 799 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus comprising:
an array of memory cells;
sensing circuitry coupled to the array of memory cells;
a processing unit (PU) coupled to the sensing circuitry; and
phase shift circuitry, coupled to the sensing circuitry and the PU, configured to:
receive a column select signal from the PU;
generate additional column select signals using the column select signal and a phase shifted clock signal;
provide the column select signal and the additional column select signals to the array of memory cells to access a plurality of lookup tables representing activation functions used to implement a machine learning model.

2. The apparatus of claim 1, wherein the phase shift circuitry is further configured to receive the column select signal from the PU via a column decoder.

3. The apparatus of claim 2, wherein the PU is configured to provide the column select signal to a multiplexor and wherein the multiplexor provides the column select signal to the phase shift circuitry.

4. The apparatus of claim 3, wherein the multiplexor is configured to:
receive the column select signal from the PU and a different column select signal from bank logic; and
provide one of the column select signal or the different column select signal to the column decoder based on a control signal received from a bank controller.

5. The apparatus of claim 4, further comprising a column decoder configured to provide the column select signal to the phase shift circuitry responsive to receipt of the column select signal from the multiplexor.

6. The apparatus of claim 1, wherein the PU is configured to provide a row activation signal to a row decoder and a row address and to a multiplexor coupled to the row decoder.

7. The apparatus of claim 6, wherein the multiplexor is configured to:
receive the row address from the PU and a different row address from bank logic; and
provide one of the row address or the different row address to the row decoder based on a control signal received from a bank controller.

8. The apparatus of claim 7, further comprising the row decoder configured to activate a row of the array of memory cells based on receipt of the row address and receipt of the activation signal.

9. The apparatus of claim 1, wherein the phase shift circuitry is further configured to generate the additional column select signals utilizing a plurality of flip-flops, the column select signal, and the phase shifted clock signal.

10. The apparatus of claim 9, wherein an output of each of the plurality of flip-flops is an additional column select signal from the additional column select signals and is provided to a different flip-flop from the plurality of flip-flops.

11. A method comprising:
receiving, by activation function circuitry, an accumulated result of a processing unit (PU) of a memory device;
generating, by the activation function circuitry, a column select signal based on the accumulated result;
providing the column select signal to phase shift circuitry;
generating, by the phase shift circuitry, additional column select signals utilizing the column select signal and a phase shifted clock signal; and
providing, by the phase shift circuitry, the column select signal and the column select signals to sensing circuitry of an array of memory cells to access a plurality of lookup tables representing activation functions used to implement an artificial neural network.

12. The method of claim 11, further comprising providing data from a plurality of columns of the memory array having different addresses and corresponding to the column select signal and the additional column select signals.

13. The method of claim 12, wherein data from each of the plurality of columns of the memory array is provided from the sensing circuitry to a plurality of drivers sequentially.

14. The method of claim 13, further comprising, providing the data, comprising the plurality of lookup tables, from the plurality of drivers to the PU concurrently.

15. The method of claim 14, further comprising providing the data concurrently utilizing a plurality of flip-flops and a clock signal.

16. The method of claim 15, further comprising providing a first portion of the data and a second portion of the data sequentially to a last flip-flop from the plurality of flip-flops.

17. The method of claim 16, providing the first portion and the second portion of the data from the last flip-flop concurrently.

18. An apparatus comprising:
sensing circuitry of an array of memory cells;
a processing unit (PU) coupled to the sensing circuitry;
phase shift circuitry, coupled to the sensing circuitry and the PU, configured to:
receive a column select signal from the processing unit;
generate additional column select signals using the column select signal and a phase shifted clock signal;
provide the column select signal and the additional column select signals to the array of memory cells to access a plurality of lookup tables representing activation functions used to implement an artificial neural network; and
wherein the sensing circuitry is configured to:
receive the column select signal and the additional column select signals via column select lines that are divided into a plurality of portions; and
provide the column select signal and the additional column select signals to a plurality of sense amplifiers utilizing the column select lines to cause data to be provided to drivers sequentially.

19. The apparatus of claim 18, wherein the plurality of sense amplifiers is configured to receive each of the column select signal and the additional column select signals utilizing a different portion of the plurality of portions of the column select lines.

20. The apparatus of claim 19, wherein the sensing circuitry is further configured to provide the data sequentially to a plurality of drivers responsive to sequential receipt of the column select signal and the additional column select signal.

21. The apparatus of claim 18, wherein the PU is further configured to:
responsive to a bank of a memory device being in a first mode, provide accumulated values via a plurality of global input/output lines; and
responsive to the bank of the memory device being in a second mode, provide the accumulated values to a column decoder as the column select signal to cause the column decoder to provide the column select signal to the phase shift circuitry.
